(19) United States
(12) Patent Application Publication
(10) Pub. No.: US 2005/0079682 A1
(43) Pub. Date: Apr. 14, 2005

(54) Method of manufacturing void-free shallow trench isolation layer

(76) Inventors: Mi-Jin Lee, Seoul (KR); Won-Jun Lee, Seoul (KR); In-Seak Hwang, Gyeonggi-do (KR); Byoung-Moon Yoon, Gyeonggi-do (KR)

Correspondence Address: MARGER JOHNSON & MCCOLLOM, P.C., 1030 SW MORRISON STREET, PORTLAND, OR, 97205, US

(21) Appl. No.: 10/961,908

(22) Filed: Oct. 8, 2004

(30) Foreign Application Priority Data
Oct. 10, 2003 (KR) 2003-70649

(51) Int. Cl. H01L 21/76

(52) U.S. Cl. 438/400

(57) ABSTRACT

Provided is a method of manufacturing a shallow trench isolation (STI) film without voids or added processes. In one embodiment, the method of manufacturing an STI film includes forming a pad oxide pattern film and a silicon nitride film pattern, which define an isolation region, on a semiconductor substrate, and forming a trench by etching the semiconductor substrate to a predetermined depth using the pad oxide film pattern and the silicon nitride film pattern as masks. The resultant semiconductor substrate having the trench may be then dipped in a chemical solution containing ozone to pullback side walls of the silicon nitride film pattern. Afterward, the STI film can be formed by filling the trench with an insulating film.

This application claims priority from Korean Patent Application No. 2003-70649 filed on Oct. 10, 2003, the disclosure of which is incorporated herein in its entirety by reference.

### BACKGROUND OF THE INVENTION

1. Field of Invention

The present invention relates to a method of manufacturing an isolation layer in semiconductor devices, and more particularly, to a method of manufacturing a void-free shallow trench isolation layer.

2. Description of the Related Art

As the integration density of semiconductor devices increases, a shallow trench isolation (STI) method, which requires a narrow space and has a superior isolation effect, is used increasingly for isolation of devices instead of a local oxidation of silicon (LOCOS) method, which requires a wider region. The STI method was introduced in the VLSI Technical Symposium Circulation, 1996, pp 156, and in the IEDM Technical Circulation, 1996, pp 841. An STI film can achieve isolation having fine size because it does not have a so-called bird's beak problem, i.e., horizontal widening, that occurs in the LOCOS method.

Since the design rule of semiconductor devices has been reduced below 0.1 μm, not only a pattern width of a semiconductor device, but also a trench width for forming a shallow trench isolation layer has been reduced. When a width of the trench is reduced while a depth of the trench is fixed, i.e., when an aspect ratio is increased, complete filling of a trench with a conventional silicon oxide film becomes difficult.

Conventionally, an insulating material having a superior interlayer filling characteristic, such as undoped silicate glass (USG) or high density plasma (HDP), is used to fill narrow trenches. Double filling with one of these insulating film materials has also been used. A double filling method for forming a shallow trench isolation layer will now be described with reference to FIGS. 1a through 1d.

As shown in FIG. 1a, a pad oxide film 15 and a silicon nitride film 20 are sequentially deposited on a semiconductor substrate 10. A predetermined region for isolation of the substrate 10 is exposed by patterning the silicon nitride film 20 and the pad oxide film 15. A trench 25 with a predetermined depth is formed by dry etching the substrate 10, using the silicon nitride film pattern 20 and the pad oxide film pattern 15 as etch masks. When forming the trench 25 by dry etching, the width of the trench 25 becomes narrower with increasing depth into the substrate 10, due to a lack of etching gas at greater depths. Accordingly, side walls of the trench 25 become sloped.

Next, a pre-cleaning process for repairing damage to walls of the trench 25 that may have been caused when dry etching is performed, using a mixture of a SC1 solution (including 30 wt % NH₄OH, 30 wt % H₂O₂, and deionized water) and a hydrofluoric acid (HF) solution diluted 200:1. A portion of pad oxide film 15 could be lost in the pre-cleaning process, as indicated by reference numeral 22 in FIG. 1a.

Next, referring to FIG. 1b, a sidewall oxide film 30 is formed on inner walls of the trench 25, a silicon nitride film liner 35 is formed on the sidewall oxide film 30, and a medium temperature oxide (MTO) film 40 is then formed on the resulting structure for protecting a corner of the trench 25.

Next, referring to FIG. 1c, a first buried insulating film 45, such as a USG film, is deposited on the MTO film 40, deep enough to fill the trench 25.

Then, referring to FIG. 1d, the first buried insulating film 45 is wet etched back by using a mixture of LAL solution (including HF, NHF₄, and deionized water) and a SC1 solution, thereby leaving a portion of the first buried insulating film 45 on the bottom of the trench 25. The trench 25 is then filled again by depositing a second buried insulating film 50, such as a USG film or an HDP film, to a predetermined thickness. Finally, the second buried insulating film 50 is removed by a chemical mechanical polishing (CMP) process until the surface of the silicon nitride film 20 or silicon nitride film liner 35 is exposed. This completes formation of an STI film.

However, the conventional method of forming an STI film requires a series of processes, such as deposition of a first buried insulating film, wet etching of the first buried insulating film, and deposition of a second buried insulating film for forming the double buried insulating film. Also, a side void 52 on upper edge of the trench 25 is generated when a large amount of pad oxide film 15 is removed in the pre-cleaning process and the process of wet etching the first buried insulating film.

Moreover, voids 47 and 47a are formed and increase in size in proportion to an angle θ between a wall of the trench 25 and a side wall of the silicon nitride film 20. The voids 47 and 47a are formed even if the trench is filled by depositing an insulating material having a superior filling characteristic, such as a USG film or an HDP film. When the void 47a exists in the STI film 55, a conductive material for forming a gate electrode in the following process can fill the void 47a and cause a bridge effect, that is, an unwanted electrical connection between adjacent gates.

However, if the angle θ decreases, the aspect ratio of the trench 25 decreases and the void 47a becomes less likely to be generated. To achieve this, in another conventional method, a pullback method was introduced, in which side walls of the silicon nitride film 20 are pulled back to form the same slope as the side walls of the trench 25. More specifically, the silicon nitride film 20 is treated with a phosphoric acid (H₂PO₄) solution between forming the trench 25 on the substrate 10 and before pre-cleaning the trench 25, as shown in FIG. 2. The phosphoric acid solution treatment is performed by dipping the substrate in the phosphoric acid solution at a temperature of 160° C. for a short time of about 1 minute, to remove a predetermined thickness of the side walls and upper surfaces of the silicon nitride film 20. In this way, the slope of the walls of the silicon nitride film 20 becomes similar to or the same as the slope of the walls of the trench 25.

However, since the pullback of the side walls of the silicon nitride film 20 by phosphoric acid solution treatment is performed at a high temperature, there is a high possibility of additional damage to the substrate. Also, since the use of phosphoric acid generates particles, there is a high possibility of damaging the substrate by the particles that are generated by the use of phosphoric acid. Moreover, the additional phosphoric acid treatment process further complicates the conventional process of forming an STI film.

### SUMMARY OF THE INVENTION

In one embodiment, a method of manufacturing a shallow trench isolation (STI) film includes forming a pad oxide film pattern and a silicon nitride film pattern on a semiconductor substrate, the silicon nitride film defining an isolation region; forming a trench by etching the semiconductor substrate using the pad oxide film pattern and the silicon nitride film pattern as masks; pulling back side walls of the silicon nitride film pattern by dipping the resultant semiconductor substrate having the trench in a chemical solution containing ozone; and forming an STI film by filling the trench with an insulating layer.

### BRIEF DESCRIPTION OF THE DRAWINGS

The above and other features and advantages of the invention will become more apparent by fully describing preferred embodiments of the invention with reference to the attached drawings, in which:

FIGS. 1a through 1d are cross-sectional views of stages in a conventional method of manufacturing an STI film on a semiconductor substrate;

FIG. 2 is a cross-sectional view of another conventional method of manufacturing an STI film on a semiconductor substrate;

FIGS. 3a through 3e are cross-sectional views of stages in a method of manufacturing an STI film on a semiconductor substrate according to the present invention;

FIG. 4 shows a chemical solution for pulling back of a silicon nitride film according to the present invention; and

FIG. 5 is a graph of etching depth versus concentration of HF solution containing O3.

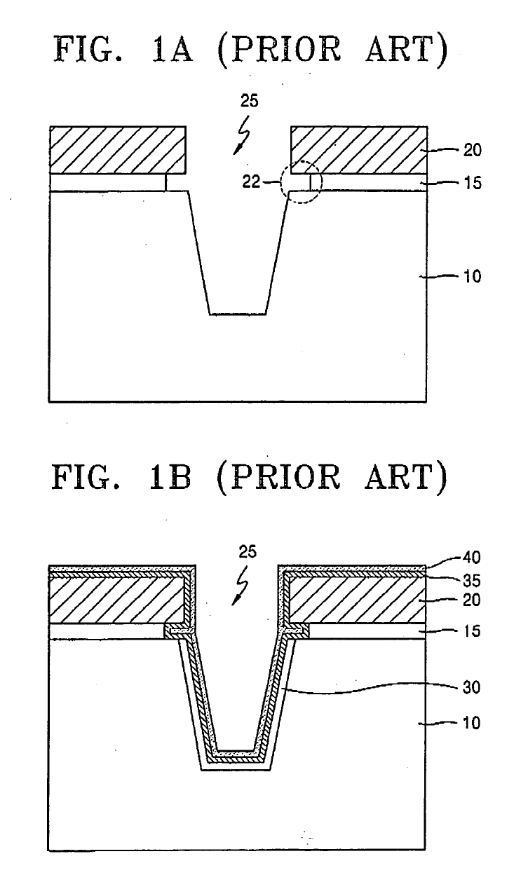

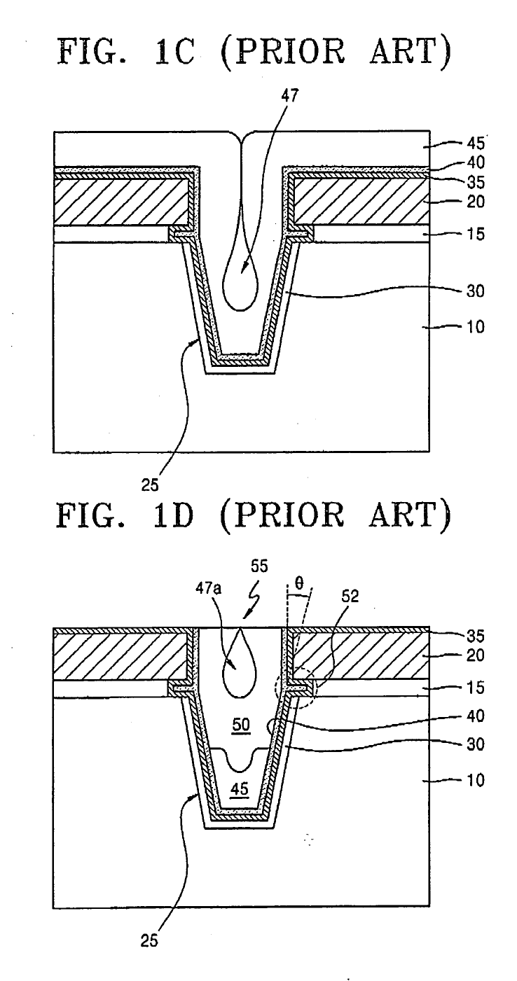

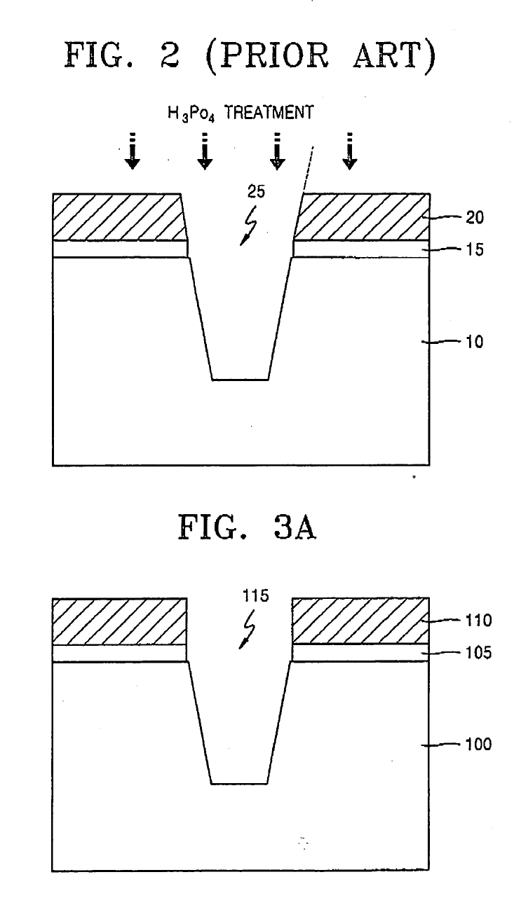

### DETAILED DESCRIPTION OF THE PREFERRED EMBODIMENTS

Hereinafter, preferred embodiments of the invention will be described more fully with reference to the accompanying drawings. This invention may, however, be embodied in many different forms and should not be construed as being limited to the embodiments set forth herein. Rather, these embodiments are provided so that this disclosure is thorough and complete, and fully conveys the concept of the invention to those skilled in the art. In the drawings, the thicknesses of layers and regions may be exaggerated for clarity, and like reference numerals denote like elements.

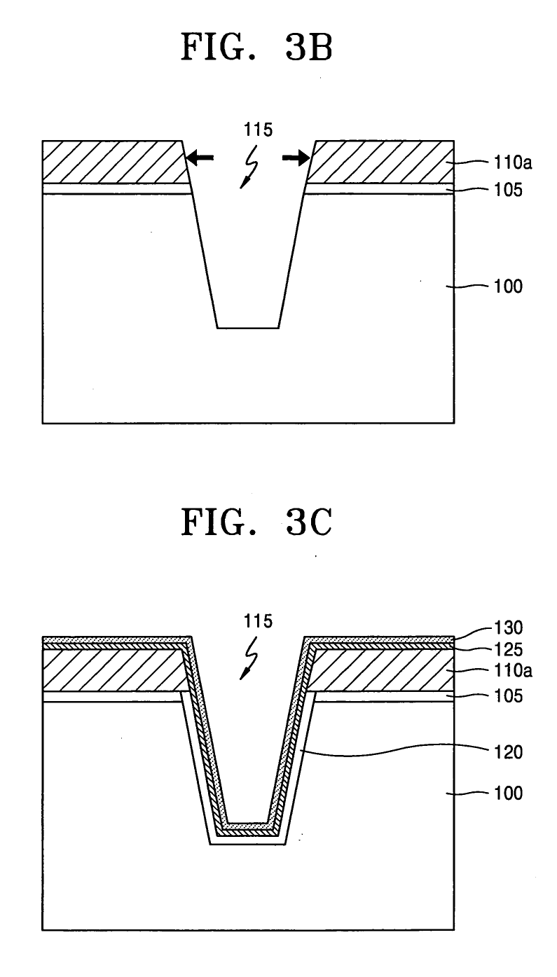

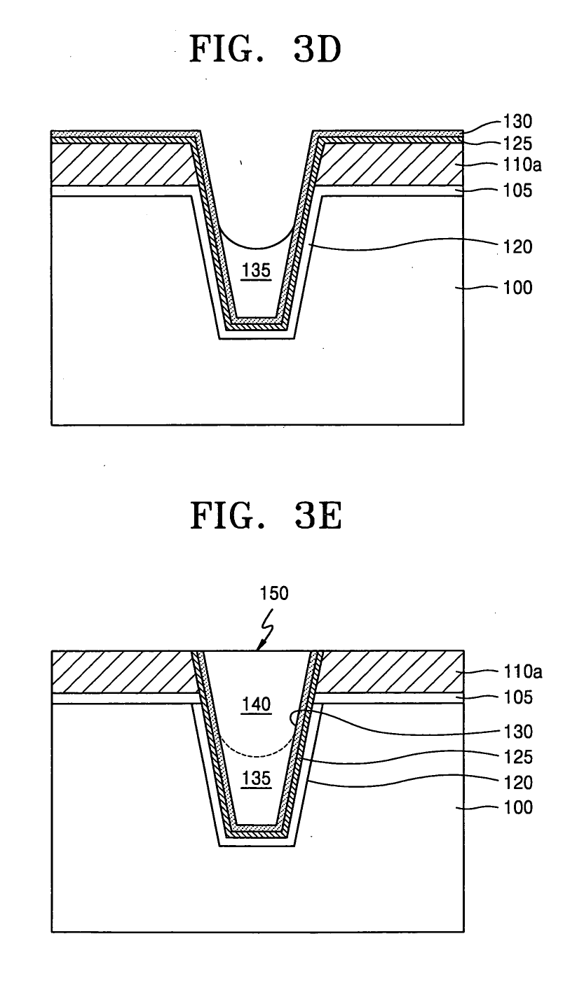

Referring to FIG. 3a, a pad oxide film 105 and a silicon nitride film 110 are sequentially deposited on a semiconductor substrate 100 such as a silicon substrate. The pad oxide film 105 can be formed by known techniques such as a thermal oxidation process, and the silicon nitride film 110 can be formed by known techniques such as a chemical vapor deposition (CVD) process. A photo-resist pattern (not shown) for defining an isolation region of devices is formed on the silicon nitride film 110. Then, the pad oxide film 105 and the silicon nitride film 110 are dry etched using the photo-resist pattern as a mask, and the photo-resist pattern is removed. Afterward, a trench 115 with a predetermined depth is formed by dry etching the exposed silicon substrate 100 using the patterned silicon nitride film 110 and the patterned pad oxide film 105 as masks. During the dry etching process to form the trench 115, the width of the trench 115 becomes narrower as it goes deeper into the substrate 100, due to a shortage of etching gas. Thus, the side walls of the trench 115 are sloped. In contrast, sidewalls of the silicon nitride film 110 are almost perfectly perpendicular to the surface of the substrate because the sidewalls are patterned by dry etching.

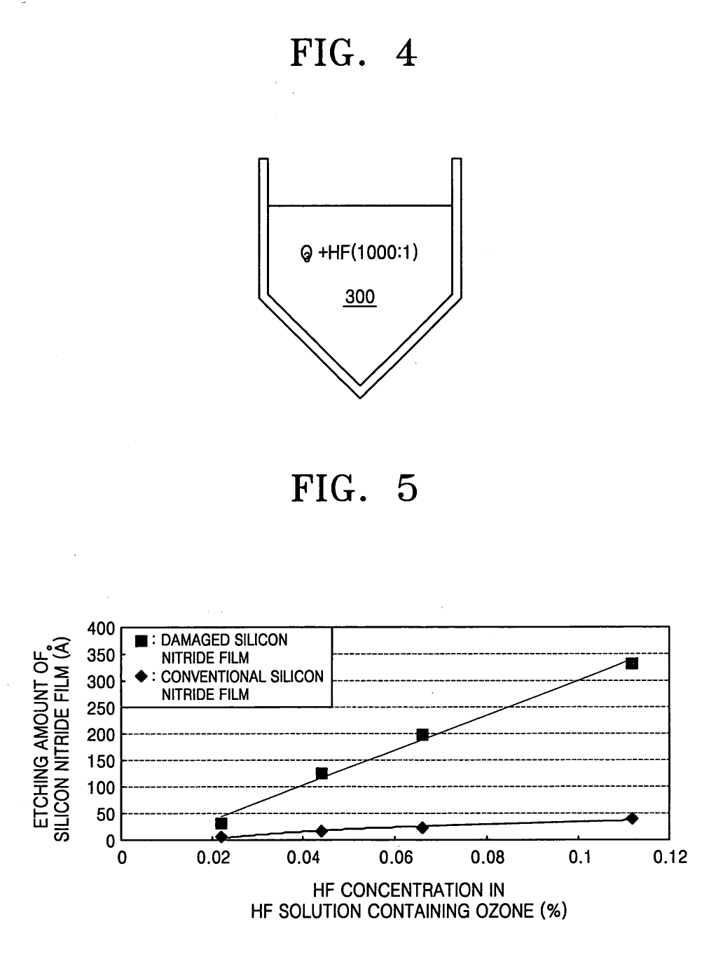

Referring to FIG. 3b, the sidewalls of the silicon nitride film 110 are pulled back to form a smooth slope with the side walls of the trench 115. The pullback process according to an embodiment of the invention may be performed by dipping the resultant semiconductor substrate 100 having the trench 115 in a chemical solution 300 containing ozone (O₃). Preferably, the chemical solution 300 is a low-concentration (about 1000:1) HF solution with ozone dissolved in it, as shown in FIG. 4.

It is known that, generally, a silicon nitride film is not etched in an HF solution containing ozone. However, according to the principles of the present invention, the silicon nitride film 220 damaged by dry etching for forming the trench 115 can be etched to a predetermined thickness in a low-concentration HF solution containing ozone, as referred in FIG. 5.

FIG. 5 is a graph of etching thickness versus concentration of HF, when the substrate 100 in the state shown in FIG. 3a is dipped in a low-concentration HF solution containing approximately 22 ppm of ozone.

Referring again to FIG. 3b, the silicon nitride film 110a is etched by a predetermined thickness in a low-concentration HF solution containing ozone, and the slope of the sidewalls of the silicon nitride film 110a smoothly matches the slope of the sidewalls of the trench 115. When etching in the low-concentration HF solution containing ozone, damage to the inner walls of the trench 115 and the pad oxide film can be cured at the same time by the HF component in the solution. Moreover, the HF component in the HF solution containing ozone does not significantly etch the edge portions of the pad oxide film 105 because the HF is highly diluted (about 1,000:1).

Referring to FIG. 3c, a side wall oxide film 120 with a thickness in the range of 20˜100 Å is formed on the inner walls of the trench 115 by known techniques such as thermal oxidation. The side wall oxide film 120 is provided for rounding the corner of the trench 115. A liner 125 for buffering stress that could result from a difference in expansion coefficient between the side wall oxide film 120 and a buried insulating film, which will be formed in the following process, is formed on the sidewall oxide film 120. The liner 125 can be formed of a silicon nitride film having a thickness in the range of about 50˜100 Å. Alternatively, the liner 125 may be omitted. An oxide film such as an MTO film 130 having a thickness in the range of about 10˜50 Å may be formed on the liner 125. The MTO film 130 can be deposited by known techniques such as a CVD process and is provided for protecting corners of the trench 115 from plasma damage which can occur when depositing an HDP film, i.e., a buried insulating film, in the following process, and for preventing an electric field concentration.

Referring to FIG. 3d, a first buried insulating film 135, such as an USG film or a HDP film, is deposited on the MTO film 130 to a thickness enough to fill the trench 115. In this case, the first buried insulating film 135 is deposited in the trench 115 without voids because the side walls of the trench 115 and the silicon nitride film 110 have a smooth slope. Next, a wet etch back process is performed to leave only a portion of the first buried insulating film 135 at the bottom of the trench 115. At that time, the wet etch back process is performed by, for example, dipping the semiconductor substrate 100 having the first buried insulating film 135 in a mixture of a LAL solution and a SC1 solution for a predetermined time. Although the dipping method has been used for etching back of the semiconductor substrate 100, One skilled in the art will appreciate that other methods besides dipping can also be used to etch back the semiconductor substrate 100 having the first buried insulating film 135 as long as it is suitable to leave only a portion of the first buried insulating film 135 at the bottom of the trench 115. The first buried insulating film 135 remaining at the bottom of the trench 115 improves the aspect ratio of the trench 115.

Referring to FIG. 3e, a second buried insulating film 140 is deposited on the semiconductor substrate 100 covering the first buried insulating film 135 remaining at the bottom of the trench 115, to a thickness that is enough to fill the trench 115. The second buried insulating film 140 can be formed of, for example, a USG film or an HDP film. The second buried insulating film 140 can be deposited without voids because the side walls of the trench 115 and the silicon nitride film 110 have a smooth slope, and the trench 115 has an improved aspect ratio because of the first buried insulating film 135 remaining at the bottom of the trench 115. Afterward, the second buried insulating film 140 is planarized until the surface of the silicon nitride film is exposed. The planarization process may be performed by a CMP process. This completes formation of a shallow trench isolation (STI) film 150.

According to an embodiment of the invention, a semiconductor substrate, having a trench that penetrates through a silicon nitride film with vertical side walls defining an isolation region, and through the substrate itself with sloping side walls, may be dipped in a low-concentration HF solution containing ozone preferably at room temperature. Thus, the side walls of the silicon nitride film are pulled back toward an active region by a predetermined thickness, so that they form a continuous, smooth slope with the side walls of the trench through the substrate. This smooth, continuous slope between side walls of the silicon nitride film and side walls of the trench notably reduces the voids in the trench when filling the trench with a buried insulating film.

Also, the pullback process cures dry etching damage that may have occurred on the walls of the trench. Accordingly, since pulling back of the silicon nitride film and curing of the internal walls of the trench can be performed at the same time, process simplicity can be achieved.

Also, etching of edges of the pad oxide film can be reduced since the pullback process and the damage curing process are performed with a low-concentration HF solution containing ozone. Accordingly, side voids caused by etched-back edge portions of the pad oxide film when filling the trench with a buried insulating film can be reduced.

Also, damage sometimes caused by the high temperature and particles generated in the phosphoric acid solution of the conventional pullback process for the side walls of the silicon nitride film can be avoided, because no high-temperature phosphoric acid process is used in the present invention.

While this invention has been particularly shown and described with reference to preferred embodiments thereof, it will be understood by those skilled in the art that various changes in form and details may be made therein without departing from the spirit and scope of the invention as defined by the appended claims.

1. A method of manufacturing a shallow trench isolation (STI) film, the method comprising:
forming a pad oxide film pattern and a silicon nitride film pattern on a semiconductor substrate, the silicon nitride film defining an isolation region;
forming a trench by etching the semiconductor substrate, using the pad oxide film pattern and the silicon nitride film pattern as etch masks;
dipping the resultant semiconductor substrate having the trench in a chemical solution containing ozone; and
forming an STI film by filling the trench with an insulating layer.

2. The method of claim 1, wherein the chemical solution containing ozone is a low-concentration HF solution containing ozone in which HF is diluted to a ratio of about 1000:1.

3. The method of claim 2, wherein dipping the resultant semiconductor substrate having the trench in the low-concentration HF solution containing ozone is performed for about 30˜90 seconds at about 20˜30° C.

4. The method of claim 1, after dipping the resultant semiconductor substrate and before forming the STI film, further comprising:
forming a sidewall oxide film on inner walls of the trench; and
forming an additional oxide film to protect corners of the trench on the side wall oxide film.

5. The method of claim 4, after forming the sidewall oxide film on the trench wall and before forming the additional oxide film, further comprising:
forming a silicon nitride film liner on the surface of the side wall oxide film.

6. The method of claim 1, wherein forming the STI film comprises:
depositing a first buried insulating film to fill the trench;
etching back the first buried insulating film to leave only a portion of the first buried insulating film at the bottom of the trench;
depositing a second buried insulating film over the first buried insulating film to fill the trench; and
planarizing the second buried insulating film until a top surface of the silicon nitride film pattern is exposed.

7. The method of claim 6, wherein the first and the second buried insulating films each comprise at least one of an undoped silicate glass (USG) film and a high density plasma (HDP) film.

8. The method of claim 7, wherein etching back the first buried insulating film comprises dipping the first buried insulating film in a mixture of an LAL solution and an SC1 solution.

9. A method of manufacturing a shallow trench isolation (STI) film, the method comprising:
forming a pad oxide film pattern and a silicon nitride film pattern on the semiconductor substrate, the silicon nitride film defining an isolation region;
forming a trench by etching the semiconductor substrate, using the pad oxide film pattern and the silicon nitride film pattern as masks;
pulling back side walls of the silicon nitride film pattern by dipping the resultant semiconductor substrate having the trench in a low-concentration HF solution containing ozone;
forming a first buried insulating film to fill a bottom portion of the trench; and
forming an STI film by filling the trench with a second buried insulating film overlying the first buried insulating film.

10. The method of claim 9, wherein in the low-concentration HF solution containing ozone, HF is diluted to a ratio of about 1000:1.

11. The method of claim 9, wherein the dipping of the resultant semiconductor substrate in the low-concentration HF solution containing ozone is performed for about 30˜90 seconds at about 20˜30° C.

12. The method of claim 9, after pulling back the side walls of the silicon nitride film and before forming the first buried insulating film, further comprising:
forming a side wall oxide film on inner walls of the trench; and
forming an insulating film to protect corners of the trench on the side wall oxide film.

13. The method of claim 12, after forming the side wall oxide film on the inner walls of the trench and before forming the insulating film, further comprising:
forming a silicon nitride film liner on the surface of the side wall oxide film.

14. The method of manufacturing of claim 9, wherein each of the first and the second buried insulating films comprises at least one of an undoped silicate glass (USG) film and a high density plasma (HDP) film.

15. The method of manufacturing of claim 9, wherein forming the first buried insulating film comprises:
depositing the first buried insulating film to fill the trench; and
etching back the first buried insulating film to leave a portion of the first buried insulating film at the bottom of the trench.

16. The method of claim 15, wherein the etching back of the first buried insulating film comprises dipping the first buried insulating film in a mixture of an LAL solution and an SC1 solution.

17. The method of manufacturing of claim 9, wherein the forming of the STI film comprises:
depositing the second buried insulating film to fill the trench; and
planarizing the second buried insulating film until a top surface of the silicon nitride film pattern is exposed.

18. A method of manufacturing a shallow trench isolation (STI) film, comprising:
forming a pad oxide film pattern and a silicon nitride film pattern on a semiconductor substrate, the silicon nitride film defining an isolation region;
etching the semiconductor substrate using etch masks to form a trench therein;
contacting the resultant semiconductor substrate having the trench with a chemical solution containing ozone, thereby pulling back side walls of the silicon nitride film pattern.

19. The method of claim 18, further comprising:
filling the trench with an insulating layer.

20. The method of claim 18, wherein the chemical solution containing ozone is a low-concentration HF solution containing ozone.
